(19) United States
(12) Patent Application Publication
(10) Pub. No.: US 2024/0334641 A1
(43) Pub. Date: Oct. 3, 2024

(54) ELECTRONICS ARRANGEMENT AND SEMICONDUCTOR SWITCHING DEVICE HAVING THE ELECTRONICS ARRANGEMENT

(71) Applicant: Siemens Aktiengesellschaft, München (DE)

(72) Inventors: Matthias Eisner, Neukirchen (DE); Nina Müller, Amberg (DE)

(21) Appl. No.: 18/619,681

(22) Filed: Mar. 28, 2024

(30) Foreign Application Priority Data
Mar. 28, 2023 (DE) 10 2023 202 837.9

(51) Int. Cl. H05K 7/20; H01L 23/367; H01L 23/467

(52) U.S. Cl. CPC H05K 7/20145; H01L 23/3672; H01L 23/467

(57) ABSTRACT

An electronics arrangement contains a printed circuit board (PCB), a semiconductor device and a heat sink. A first side of the semiconductor device points toward the PCB and a second side, opposite the first side, bears the heat sink, which is thermally connected to the semiconductor device. A fan is provided for producing an airflow flowing around the heat sink. An air guide device is mounted on the PCB and is configured such that, together with the PCB, it forms an air duct having an air duct inlet and an air duct outlet. The airflow flowing into the air duct flows through the air duct inlet and leaves through the air duct outlet. The air guide device has an air guide ramp that is arranged in the area of the air duct inlet such that the airflow flowing into the air duct inlet is deflected toward the heat sink.

### CROSS-REFERENCE TO RELATED APPLICATION

This application claims the priority, under 35 U.S.C. § 119, of German Patent Application DE 10 2023 202 837.9, filed Mar. 28, 2023; the prior application is herewith incorporated by reference in its entirety.

### FIELD AND BACKGROUND OF THE INVENTION

The present invention relates to an electronics arrangement and a semiconductor switching device.

In a semiconductor (SC) switching device, the power semiconductors installed in it represent the greatest heat source (SC=semiconductor). The thermal energy released by the power semiconductors during continuous operation or motor start-up is a critical factor in the design of electronic and mechanical components and for the classification of the operating conditions such as rated current, starting current and maximum permissible ambient temperature. In order to dissipate the heat generated in an SC switching device, free convection is usually sufficient at low currents; at higher currents, a fan is often required in order to achieve a higher level of heat dissipation through forced convection.

At higher currents, heat sinks, which are usually produced from a metal such as aluminum, may also be necessary. Such a heat sink is arranged on a power semiconductor in such a way that effective heat conduction from the power semiconductor to the heat sink is possible.

The ideal arrangement of a fan in relation to a heat sink is such that the greatest possible airflow at the highest possible pressure is routed over the heat-emitting surfaces, in particular the cooling fins, of the heat sink. The flow resistances resulting from the components of the SC switching device, including the heat sink, must be kept as low as possible here. Typically, a favorable arrangement in terms of flow is achieved when the center axes of the fan and the heat sink coincide.

However, the optimum position of the fan relative to the heat sink cannot always be selected due to circumstances such as grid dimensions of the fan or the heat sink, specifications regarding design, function or production, standard specifications, etc.; air and creepage distances between heat sinks and adjacent electronic components, which must also be observed for electrical insulation, are also a factor here. In addition, heat sinks that are open on one side, e.g. having a comb cross section, experience a “bypass effect” as length increases: The airflow does not flow along the cooling fins of the heat sinks, but rather swerves toward the open side. The cause of the “bypass effect” is that flowing around heat sinks (“bypass”) takes less energy than flowing through them, i.e. the airflow looks for the path of least resistance and leaves the cooling duct. All of this means that the cooling effect of a fan cooling system can be severely impaired.

### SUMMARY OF THE INVENTION

The object of the present invention is improved routing of the cooling air of a fan for removing heat from an electronics arrangement.

This object is achieved according to the invention by an electronics configuration. The electronics configuration contains a printed circuit board, at least one semiconductor device having a first side and a second side, and at least one heat sink. The first side of the at least one semiconductor device points toward the printed circuit board and the second side, opposite the first side, of the at least one semiconductor device bears the at least one heat sink, which is thermally connected to the at least one semiconductor device. A fan is provided for producing an airflow flowing around the at least one heat sink. An air guide device is mounted on the printed circuit board and is configured such that, together with the printed circuit board, forms an air duct having an air duct inlet and an air duct outlet. The airflow flowing into the air duct through the air duct inlet and leaving the air duct again through the air duct outlet. The air guide device has an air guide ramp disposed in an area of the air duct inlet such that the airflow flowing into the air duct inlet is deflected toward the at least one heat sink.

The electronics arrangement has a printed circuit board (PCB). The printed circuit board may have contact points suitable for receiving connection pins of SC devices. The contact points may have through holes here that extend transversely to the plane of the printed circuit board. The semiconductor device has electrical connections that make contact with corresponding contact points of the printed circuit board.

The electronics arrangement has at least one semiconductor device and at least one heat sink.

The semiconductor device may in particular be a power semiconductor or a power semiconductor module. For power semiconductors, a distinction is made between SMD (surface-mounted device) and THT (through-hole technology) components. THT components, e.g. THT MOSFETs (Metal Oxide Semiconductor Field Effect Transistor), stand upright on the printed circuit board, i.e. the body of a THT component projects from the printed circuit board at right angles. In contrast, SMD components, e.g. SMD MOSFETs, are installed horizontally on the printed circuit board, which is why they require significantly less installation space in terms of height, i.e. in the direction at right angles to the printed circuit board, than THT components. Both types of devices are suitable for the electronics arrangement according to the invention.

The semiconductor device may have a plate-shaped package. The package may be made of an electrically insulating material such as polymers, or of a plastic. The package may have a top, a bottom opposite the top, and edge sides that connect the top and the bottom to one another. The semiconductor device may also have connection pins that protrude from the package.

The semiconductor device may have a first side and a second side opposite the first side; for example, the semiconductor device is plate-shaped, having a first side forming a bottom, a second side forming a top, and 4 edge sides.

If the semiconductor device is in the form of an SMD component, the first side (bottom) of the semiconductor device may point toward the printed circuit board; the first side of the semiconductor device may rest on the printed circuit board here. In addition, the semiconductor device may bear the heat sink on the second side (top).

If the semiconductor device is in the form of a THT component, the first side (bottom) of the semiconductor device may be adjacent to the heat sink. The second side (top) of the semiconductor device may support a spring element that presses the semiconductor device against the heat sink.

The heat sink is thermally conductively connected to the semiconductor device here. The heat sink and the semiconductor device may have an intermediate layer arranged between them that may be in the form of a heat-conducting film or in the form of a layer consisting of a heat-conducting paste.

The heat sinks are made of a thermally conductive material. This may be a metallic material, preferably an easy-to-machine metal with a relatively low density such as aluminum. However, the heat sinks may also be made of a non-metallic material, e.g. a thermally conductive polymer, preferably a polymer with additives which increase the thermal conductivity of the polymer.

The electronics arrangement has a fan that is used to produce an airflow flowing around the heat sink. Preferably, the fan is in the form of an axial fan.

The electronics arrangement also has an air guide device mounted on the printed circuit board. The air guide device is configured in such a way that, together with the printed circuit board, it forms an air duct having an air duct inlet and an air duct outlet. Here, the airflow flows into the air duct through the air duct inlet and leaves the air duct again through the air duct outlet.

The air guide device has an air guide ramp that is arranged in the area of the air duct inlet in such a way that the airflow flowing into the air duct inlet is deflected toward the at least one heat sink.

The invention is based on the finding that the bypass effect of the airflow can be effectively prevented by an air guide device mounted on the printed circuit board. The airflow is forced by the air guide device to flow along the heat sinks in a cooling duct, resulting in effective removal of heat from the heat sinks. Due to the optimized routing of the cooling air and the resulting improved removal of heat from the electronics arrangement, a smaller and therefore less expensive fan can be used. Since the optimized routing of the cooling air allows the cooling surface to be reduced, the heat sinks can be designed more compactly, as a result of which they have a higher thermal capacity. Due to their higher thermal capacity, the heat sinks can be better designed for high, short starting currents.

According to the invention, the object is also achieved by an SC switching device having an electronics arrangement according to one of the preceding claims. The advantage of this is that the optimized routing of the cooling air in the electronics arrangement allows smaller heat sinks to be used. It is therefore possible for the size of the SC switching device to be reduced. The SC switching device may be e.g. an electronic motor starter, a soft starter, an electronic miniature circuit breaker or a frequency converter. This list contains examples only and is neither exhaustive nor limiting. The SC switching device may be any device that has MOSFETS, thyristors, IGBTs or diodes and needs to be cooled.

Advantageous embodiments and developments of the invention are specified in the dependent claims.

According to a preferred embodiment of the invention, the air guide device has one or more air guide fins that are arranged in the area of the air duct inlet in such a way that the airflow is directed into the air duct inlet. The advantage of this is that the fins reduce the flow resistance of the heat sink cross section and direct the flow air. It is therefore possible for turbulence in the airflow to be greatly minimized, or eliminated.

According to a preferred embodiment of the invention, the air guide device has a cover plate that is arranged in such a way that the semiconductor devices and the heat sinks are located between the printed circuit board and the cover plate. The air duct inlet and the air duct outlet are each arranged here between the cover plate and the printed circuit board.

It is possible for the air duct inlet to stretch from a first edge of the cover plate to the printed circuit board. It is possible for the air duct outlet to stretch from a second edge of the cover plate opposite the first edge of the cover plate to the printed circuit board.

According to a preferred embodiment of the invention, the cover plate is arranged parallel to the printed circuit board.

According to a preferred embodiment of the invention, the air guide device has at least one lateral apron that is arranged between the cover plate and the printed circuit board and laterally delimits the air duct between the air duct inlet and the air duct outlet.

According to a preferred embodiment of the invention, the fan is arranged in such a way that the airflow flows parallel to the printed circuit board.

According to a preferred embodiment of the invention, at least one of the heat sinks has an arrangement of cooling fins that have a comb profile whose end face points toward the air duct inlet. The advantage of this is that the airflow flows along the cooling fins and therefore effectively removes heat from the heat sink.

According to a preferred embodiment of the invention, the air guide device is made of a plastic. The advantage of this is that the air guide device forms an electrical insulation layer. To be able to maintain the necessary electrical insulation between components at different electrical potentials in an SC switching device, there are two options: sufficiently large air gaps between the components or additional insulating separators between the components, the separators producing structural insulation between the components. The advantage of the latter option, i.e. the additional insulating separators between the components, is that the distances between the components that are at different electrical potentials can be chosen to be shorter than with insulation by an air gap only. Due to the confined installation space in the switching devices, it is often not possible to maintain sufficiently great distances between the components that are at different electrical potentials; in this case, the air guide device according to the invention made of a plastic, i.e. an electrically insulating material, provides the required structural insulation.

According to a preferred embodiment of the invention, each of the semiconductor devices has its own respective heat sink. The semiconductor devices may be at different electrical potentials. As a result of each of the semiconductor devices having their own respective, separate heat sink, the heat sinks are electrically insulated from one another. The advantage of this is that no insulation film is required between a semiconductor device and a heat sink arranged on the semiconductor device, which results in an improvement in the heat transfer from the semiconductor device to the heat sink and therefore in improved removal of heat from the semiconductor device.

As a result of each of the semiconductor devices having their own respective heat sink, free license exists for the arrangement of the semiconductor devices on the printed circuit board and the semiconductor devices can be arranged e.g. in such a way that efficient flow routing in the printed circuit board is achieved. Efficient flow routing in the printed circuit board can mean that a varistor needs to be placed locally between two semiconductor devices, e.g. MOSFETs.

According to a preferred embodiment of the invention, the air guide device is in integral form. As a result of the air guide device combining multiple functions (electrical insulation, ramp for directing air, fins for routing air) in a single part, there is no longer a requirement for additional components for routing air such as baffles or partitions.

Other features which are considered as characteristic for the invention are set forth in the appended claims.

Although the invention is illustrated and described herein as embodied in an electronics arrangement, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, cross-sectional view of an electronics arrangement according to the invention;

FIG. 2 is a longitudinal sectional view of the electronics arrangement of FIG. 1;

FIG. 3 is a perspective view of a first embodiment of an electronics arrangement;

FIG. 4 is a perspective view of a conventional electronics arrangement according to the prior art;

FIG. 5 is a perspective and longitudinal sectional view of an SC switching device according to the invention;

FIG. 6 is a longitudinal sectional view of the SC switching device; and

FIG. 7 is a perspective view of an alternative embodiment of the electronics arrangement.

### DETAILED DESCRIPTION OF THE INVENTION

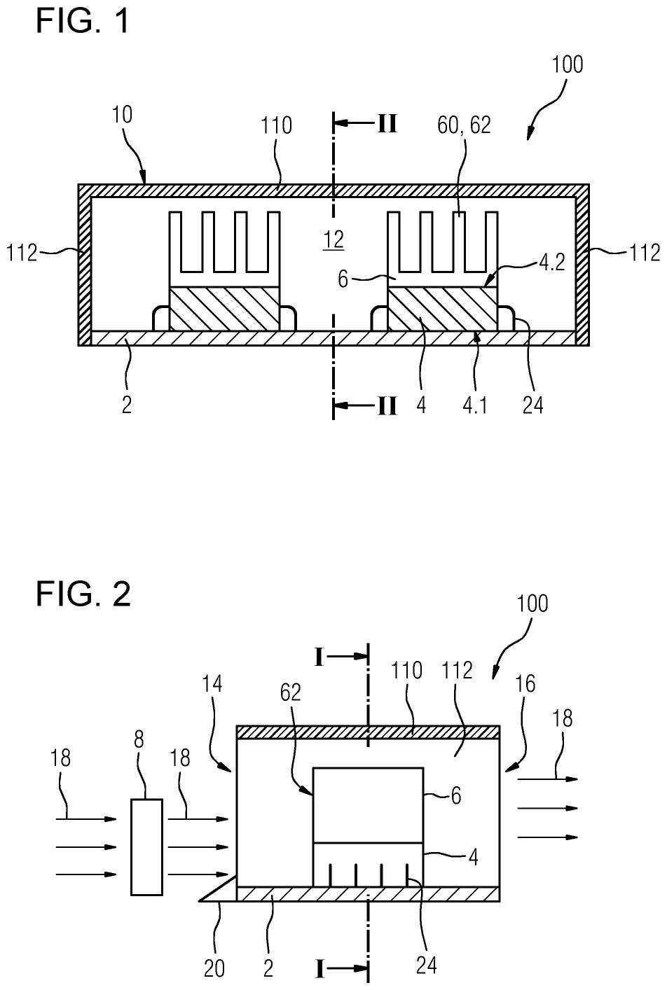

Referring now to the figures of the drawings in detail and first, particularly to FIG. 1 thereof, there is shown an electronics arrangement 100 in cross section along a sectional plane I-I indicated in FIG. 2. The electronics arrangement 100 has a printed circuit board 2 (PCB) with semiconductor devices 4 arranged thereon. The semiconductor devices 4 are in the form of SMD components soldered directly to the printed circuit board 2 by means of solderable connection pins 24. The electrical connection pins 24 of the SMD components 4 are each in electrical contact with conductor structures extending in the printed circuit board 2. A first side 4.1 of each of the semiconductor devices 4 points toward the printed circuit board 2 here.

A second side 4.2, opposite the first side 4.1, of each of the semiconductor devices 4 bears a heat sink 6. The semiconductor devices 4 are thermally connected here to their respective heat sink 6, e.g. by means of a thermally conductive intermediate layer between the semiconductor device 4 and the heat sink 6. The heat sinks each have an arrangement of four cooling fins 60; the arrangement has a comb profile in cross section here.

An air guide device 10, which has a cover plate 110 and two lateral aprons 112, is mounted on the printed circuit board 2. The cover plate 110 is arranged parallel to the printed circuit board 2 in such a way that the semiconductor devices 4 and the heat sinks 6 are located between the printed circuit board 2 and the cover plate 110. The lateral aprons 112 are arranged at right angles to the printed circuit board 2 between the cover plate 110 and the printed circuit board 2. The cover plate 110, the two lateral aprons 112 and the printed circuit board 2 form an air duct 12. The semiconductor devices 4 and the heat sinks 6 are arranged in the air duct 12.

FIG. 2 shows a longitudinal section of the electronics arrangement 100 of FIG. 1 along the sectional plane II-II indicated in FIG. 1. The air duct 12 formed by the cover plate 110, the two lateral aprons 112 and the printed circuit board 2 has an air duct inlet 14 and an air duct outlet 16. The air duct inlet 14 and the air duct outlet 16 are each arranged here between the cover plate 110 and the printed circuit board 2.

The electronics arrangement 100 has an electrically driven fan 8 for producing an airflow 18 flowing around the heat sinks 6. The fan 8 is arranged in such a way that the airflow 18 flows parallel to the printed circuit board 2. Here, the airflow 18 flows into the air duct 12 through the air duct inlet 14 and leaves the air duct 12 again through the air duct outlet 16.

The air guide device 10 also has an air guide ramp 20 that is arranged in the area of the air duct inlet 14 in such a way that the airflow 18 flowing into the air duct inlet 14 is deflected upward toward the heat sinks 6. The deflection of the airflow 18 at the air guide ramp 20 directs the airflow 18 onto the heat-emitting heat sinks 6, thereby improving the removal of heat from the electronics arrangement 100.

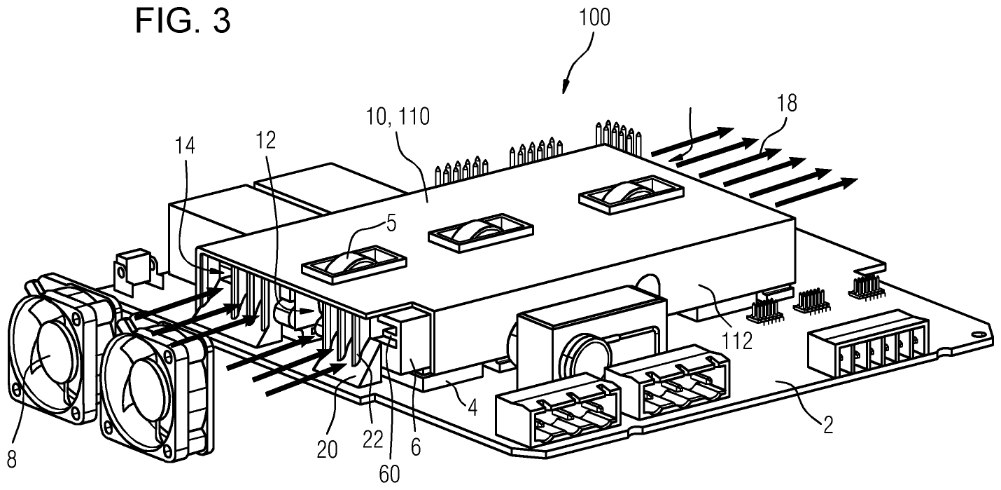

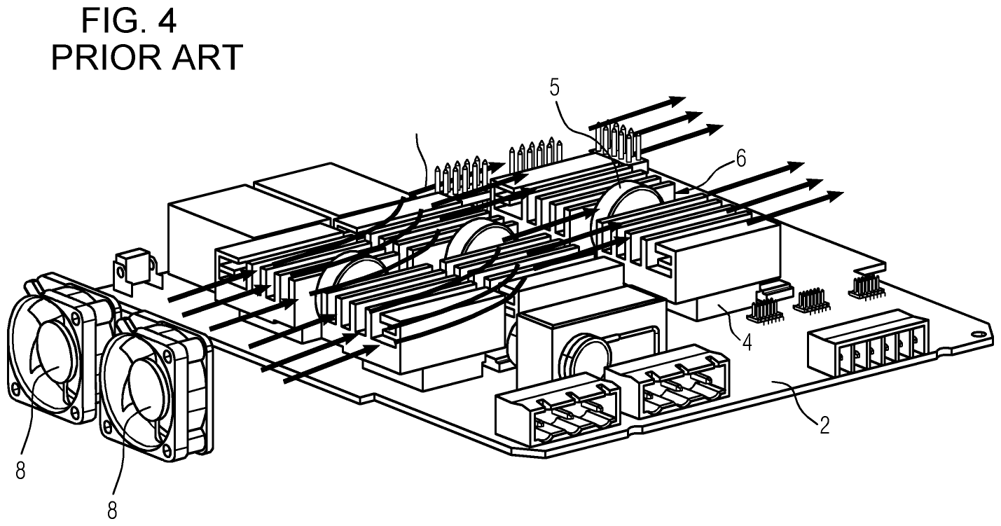

FIG. 3 is an oblique view of an electronics arrangement 100 according to the invention. A printed circuit board 2 has semiconductor devices 4, here: power semiconductor modules, arranged on it, each of which bears the heat sink 6, which has the cooling fins 60, on a side facing away from the printed circuit board 2. The heat sinks 6 are thermally connected to the corresponding semiconductor device 4.

Fitted over the printed circuit board 2 is the air guide device 10, which has a rectangular cover plate 110 arranged parallel to the printed circuit board 2 and two rectangular lateral aprons 112, each attached to opposite edges of the cover plate 110, that extend parallel to one another and at right angles to the printed circuit board 2. Together with the printed circuit board 2, the air guide device 10 forms an air duct 12 having an air duct inlet 14 and an air duct outlet 16. The semiconductor devices 4 and the heat sinks 6 are arranged in the air duct 12.

The electronics arrangement 100 also has two fans 8 that produce an airflow 18 flowing around the heat sinks 6. Here, the airflow 18 flows into the air duct 12 through the air duct inlet 14 and leaves the air duct 12 again through the air duct outlet 16.

In addition, the air guide device 10 has the air guide ramp 20, which is formed integrally with the cover plate 110 and the lateral aprons 112 and is arranged upright on the printed circuit board in the area of the air duct inlet 14 in such a way that the airflow 18 flowing into the air duct inlet 14 is deflected toward the heat sink 6. The deflection of the airflow 18 onto the heat sinks 6 improves the removal of heat from the electronics arrangement 100.

In addition, the air guide device 10 has air guide fins 22 that extend at right angles to the printed circuit board 2, are formed integrally with the cover plate 110, the lateral aprons 112 and the air guide ramp 20 and are arranged in the area of the air duct inlet 14 in such a way that the airflow 18 flowing into the air duct inlet 14 is deflected toward the heat sinks 6. The deflection of the airflow 18 onto the heat sinks 6 improves the removal of heat from the electronics arrangement 100. The air guide fins 22 also ensure that turbulence in the airflow 18 is greatly minimized, or eliminated.

Along a center axis, the cover plate 110 has three cutouts from which the packages of three electronic components 5, here: varistors, protrude. The arrangement of the varistors 5 at precisely these positions is essential for effective flow routing within the electronics arrangement 100.

FIG. 4 is an oblique view of a conventional electronics arrangement 100 without an air guide device 10. Since there is no cover plate, the heat sinks 6 having a comb cross section are open on one side, specifically on their side facing away from the printed circuit board 2. Therefore, the airflow 18 passing through the heat sinks 6 develops a “bypass effect” as path length increases: The airflow 18 does not flow along the cooling fins 60 of the heat sinks 6, but rather swerves toward the open side thereof. As a result, the cooling effect of the fan cooling is severely impaired.

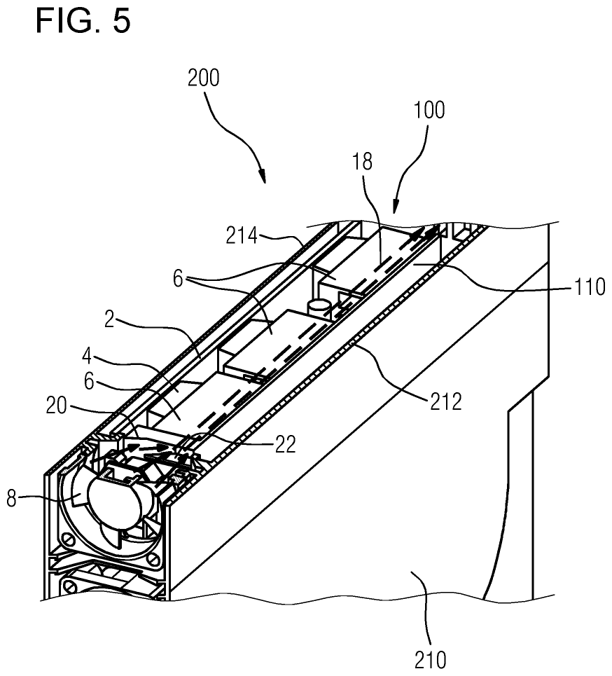

FIG. 5 shows a longitudinal section of an SC switching device 200. The package 210 of the SC switching device 200 has a package cover 212 and a package back 214 arranged parallel to the package cover 212. An electronics arrangement 100 according to the invention is arranged in an intermediate space between the package cover 212 and the package back 214. The electronics arrangement 100 has a printed circuit board 2 arranged parallel to the package back 214 at a short distance from the package back 214. On the side of the printed circuit board 2 that points toward the package cover 212, the printed circuit board 2 bears semiconductor devices 4 that bear heat sinks 6 on their side that points toward the package cover 212.

The package cover 212 and the package back 214 have two axial fans 8 arranged between them that produce an airflow 18 that flows through the intermediate space between the package cover 212 and the package back 214. Immediately after the fans 8 in the direction of flow of the airflow 18, the airflow 18 hits an air guide ramp 20 and air guide fins 22, which direct the airflow 18 toward the heat sinks 6. A cover plate 110 arranged between the heat sinks 6 and the package cover 212 and extending parallel to the package cover 212 prevents the airflow 18 from squeezing out of the heat sinks 6 and thus escaping.

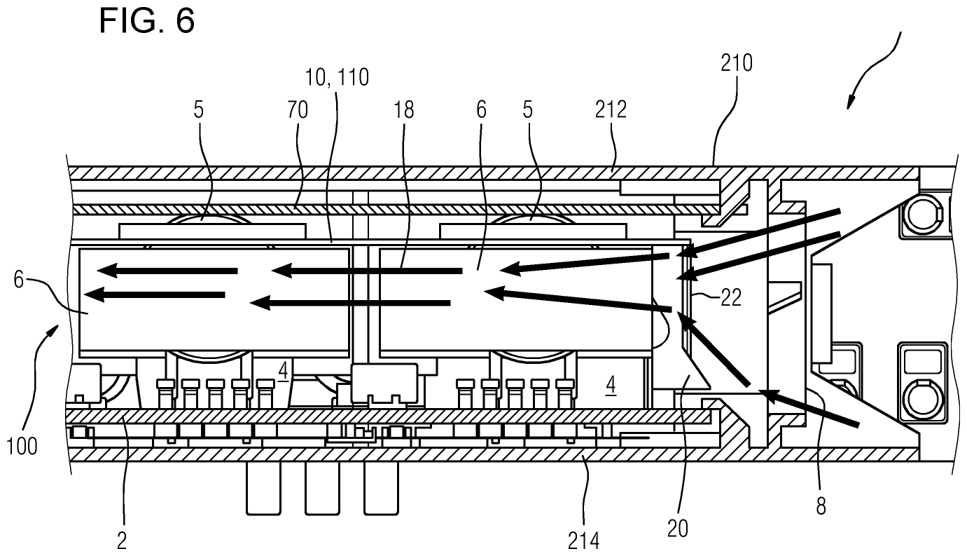

FIG. 6 shows a longitudinal section of an SC switching device 200. The package 210 of the SC switching device 200 has a package cover 212 and a package back 214 arranged parallel to the package cover 212. An electronics arrangement 100 according to the invention is arranged in an intermediate space between the package cover 212 and the package back 214. The electronics arrangement 100 has a first printed circuit board 2 arranged parallel to the package back 214 at a short distance from the package back 214. On the side of the printed circuit board 2 that points toward the package cover 212, the printed circuit board 2 bears semiconductor devices 4 that bear heat sinks 6 on their side that points toward the package cover 212.

The package cover 212 and the package back 214 have an axial fan 8 arranged between them that produces an airflow 18 that flows through the intermediate space between the package cover 212 and the package back 214. Immediately after the fan 8 in the direction of flow of the airflow 18, the airflow 18 hits an air guide ramp 20 and air guide fins 22, which direct the airflow 18 toward the heat sinks 6. A cover plate 110 of the air guide device 10 that is arranged between the heat sinks 6 and the package cover 212 and extends parallel to the package cover 212 prevents the airflow 18 from being pushed out of the heat sinks 6 and thus not being available for a heat transfer from the heat sinks 6 to the airflow 18.

The cover plate 110 and the package cover 212 have a further, second printed circuit board 70 arranged between them. Here, the first printed circuit board 2 can carry e.g. low voltage 400 V, while the second printed circuit board 70 carries e.g. control voltage 12 V. The cover plate 110, which is made of an electrically insulating plastic, ensures that the heat sinks 6 are electrically insulated from the second printed circuit board 70 as required. Were the cover plate 110 not present, at least one air gap of 8 mm would have to be maintained between the heat sinks 6 and the second printed circuit board 70 in order to meet the normative requirements according to IEC 60947-1 (as of 2020 Apr. 1). Due to the fact that the cover plate 110 has an electrically insulating effect, the distance between the heat sinks 6 and the second printed circuit board 70 can be chosen to be less than 8 mm. The dimensions of the SC switching device 200 between the package cover 212 and the package back 214 can thus be reduced, the switching device 200 made smaller.

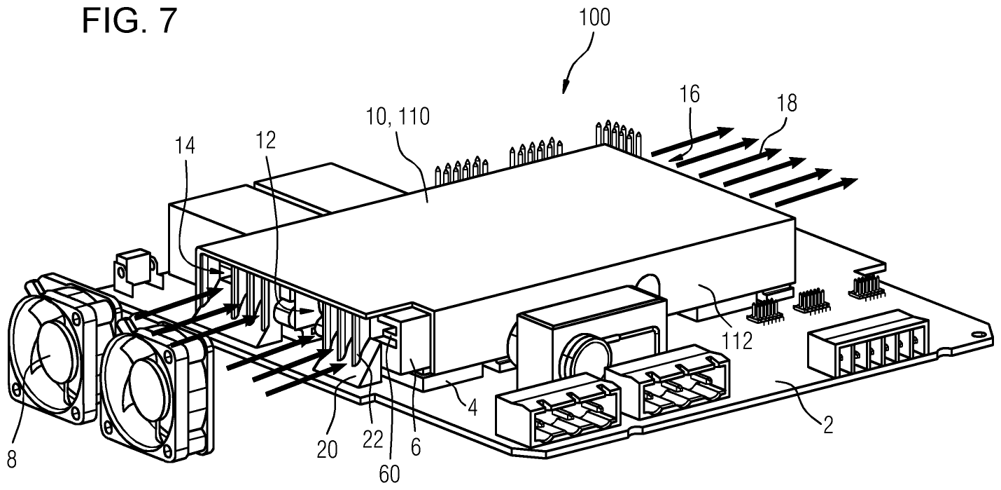

FIG. 7 shows an oblique view of an alternative embodiment of an electronics arrangement. This alternative embodiment corresponds to the embodiment shown in FIG. 3, apart from the difference that the cover plate 110 of the air guide device 10 has no cutouts from which the packages of electronic components protrude. Instead, the air guide device 10 according to FIG. 7 is configured in such a way that the electronic components 5 protruding in FIG. 3 are arranged below the cover plate 110 and are completely covered by the cover plate 110; this is achieved e.g. as a result of the lateral aprons 112 being routed further upward, i.e. in the direction facing away from the printed circuit board 2. The effect achieved by the embodiment of the cover plate 110 without cutouts (openings in the cover plate) is that an airflow 18 routed through the air guide device 10 does not suffer any flow losses at any cutouts.

1. An electronics configuration, comprising:
a printed circuit board;
at least one semiconductor device having a first side and a second side;
at least one heat sink, said first side of said at least one semiconductor device pointing toward said printed circuit board and said second side, opposite said first side, of said at least one semiconductor device bearing said at least one heat sink, which is thermally connected to said at least one semiconductor device;
a fan for producing an airflow flowing around said at least one heat sink; and
an air guide device, mounted on said printed circuit board, and configured such that, together with said printed circuit board, forms an air duct having an air duct inlet and an air duct outlet, the airflow flowing into said air duct through said air duct inlet and leaving said air duct again through said air duct outlet, said air guide device having an air guide ramp disposed in an area of said air duct inlet such that the airflow flowing into said air duct inlet is deflected toward said at least one heat sink.

2. The electronics configuration according to claim 1, wherein said air guide device has at least one air guide fin that is disposed in said area of said air duct inlet such that the airflow is directed into said air duct inlet.

3. The electronics configuration according to claim 1, wherein said air guide device has a cover plate that is disposed such that said at least one semiconductor device and said at least one heat sink are disposed between said printed circuit board and said cover plate, said air duct inlet and said air duct outlet each being disposed between said cover plate and said printed circuit board.

4. The electronics configuration according to claim 3, wherein said cover plate is disposed parallel to said printed circuit board.

5. The electronics configuration according to claim 3, wherein said air guide device has at least one lateral apron that is disposed between said cover plate and said printed circuit board and laterally delimits said air duct between said air duct inlet and said air duct outlet.

6. The electronics configuration according to claim 1, wherein said fan is disposed such that the airflow flows parallel to said printed circuit board.

7. The electronics configuration according to claim 1, wherein said at least one heat sink has a configuration of cooling fins that have a comb profile whose end face points toward said air duct inlet.

8. The electronics configuration according to claim 1, wherein said air guide device is made from plastic.

9. The electronics configuration according to claim 1, wherein:
said at least one heat sink is one of a plurality of heat sinks; and
said at least one semiconductor device is one of a plurality of semiconductor devices, each of said semiconductor devices has its own respective said heat sink.

10. The electronics configuration according to claim 1, wherein said air guide device is in integral form.

11. A semiconductor switching device, comprising:
the electronics configuration according to claim 1.
